(19) United States
(12) Patent Application Publication
(10) Pub. No.: US 2025/0185526 A1
(43) Pub. Date: Jun. 5, 2025

(54) SEMICONDUCTOR STRUCTURE AND PREPARATION METHOD THEREOF

(71) Applicant: XIAMEN INDUSTRIAL TECHNOLOGY RESEARCH INSTITUTE CO., LTD., Xiamen (CN)

(72) Inventors: Enping CHENG, Xiamen (CN); Taiwei CHIU, Xiamen (CN)

(73) Assignee: XIAMEN INDUSTRIAL TECHNOLOGY RESEARCH INSTITUTE CO., LTD., Xiamen (CN)

(21) Appl. No.: 18/931,123

(22) Filed: Oct. 30, 2024

(30) Foreign Application Priority Data
Nov. 30, 2023 (CN) 202311638521 .5

(51) Int. Cl. H10N 70/00; H10B 63/00; H10N 70/20

(52) U.S. Cl. CPC H10N 70/8418; H10B 63/80; H10N 70/066; H10N 70/24; H10N 70/826

(57) ABSTRACT

A semiconductor structure and a preparation method thereof are provided. The semiconductor structure includes: a substrate; and a plurality of resistive devices, disposed on the substrate; each of the resistive devices includes a lower electrode, a resistive layer and an upper electrode, a groove is formed in the lower electrode to form a concave structure, the resistive layer covers a side wall and a bottom of the groove and an outer surface of the lower electrode, and the upper electrode covers a surface of the resistive layer and fills the groove.

### CROSS-REFERENCE TO THE RELATED APPLICATIONS

This application is based upon and claims priority to Chinese Patent Application No. 202311638521.5, filed on Nov. 30, 2023, the entire contents of which are incorporated herein by reference.

### TECHNICAL FIELD

The present disclosure relates to the technical field of semiconductors, and in particular to a semiconductor structure and a preparation method thereof.

### BACKGROUND

A resistive random access memory (RRAM) is a non-volatile memory for storing information by using the variable resistance characteristic of a material, and has the advantages of low power consumption, high density, high read-write speed, high durability and the like.

The existing RRAM has a 1T1R structure, a resistive area (also called resistive switching area) is determined by an area of a RRAM plane, and the resistive area is limited by the area of the RRAM, such that it is difficult to miniaturize the plane and provide an integration level.

### SUMMARY

The present disclosure provides a semiconductor structure and a preparation method thereof, so as to at least solve the above technical problems in the related art.

According to a first aspect of the present disclosure, a semiconductor structure is provided and includes:
a substrate;
a plurality of resistive devices (also called resistive switching devices), disposed on the substrate; each of the resistive devices includes a lower electrode, a resistive layer and an upper electrode; a groove is formed in the lower electrode to form a concave structure, the resistive layer (also called resistive switching layer) covers a side wall and a bottom of the groove and an outer surface of the lower electrode, and the upper electrode covers a surface of the resistive layer and fills the groove.

In an embodiment, the semiconductor structure may further include:
a first dielectric layer, disposed between two adjacent upper electrodes to isolate the two adjacent upper electrodes; where the first dielectric layer may be an ultralow K material.

In an embodiment, the semiconductor structure may further include:
a first interlayer dielectric layer, a second interlayer dielectric layer and a third interlayer dielectric layer which are sequentially stacked on the substrate; where the resistive devices may be disposed on the third interlayer dielectric layer; and
a plurality of first metal layers, disposed in the second interlayer dielectric layer and penetrating through the second interlayer dielectric layer; where the first metal layers may electrically be connected to the lower electrode.

In an embodiment, the semiconductor structure may further include:
a plurality of second metal layers, disposed on the resistive devices and electrically connected to the upper electrode.

According to a second aspect of the present disclosure, a preparation method for a semiconductor structure is provided. The method includes:
providing a substrate;
forming a plurality of resistive devices on the substrate; where forming each of the resistive devices may include:
forming a lower electrode on the substrate, forming a groove in the lower electrode to form a concave structure;
forming a resistive layer, the resistive layer covering a side wall and a bottom of the groove and an outer surface of the lower electrode; and
forming an upper electrode, the upper electrode covering a surface of the resistive layer and filling the groove.

In an embodiment, the method may further include:
forming a first dielectric layer disposed between two adjacent upper electrodes to isolate the two adjacent upper electrodes; where the first dielectric layer may be an ultralow K material.

In an embodiment, the forming the lower electrode may include:
forming a first mask layer on the substrate;
etching the first mask layer to form a plurality of first grooves penetrating
through the first mask layer;
forming an initial lower electrode covering side walls and bottoms of the first grooves and a surface of the first mask layer; and
etching and removing the initial lower electrode disposed on the surface of the first mask layer, and retaining the initial lower electrode covering the side walls and the bottoms of the first grooves to form the lower electrode; where a groove may be formed in the lower electrode to form the concave structure.

In an embodiment, the method may further include: before forming the resistive devices,
forming a first interlayer dielectric layer, a second interlayer dielectric layer and a third interlayer dielectric layer which are sequentially stacked on the substrate;
where the first mask layer may be disposed on the third interlayer dielectric layer, and a material of the first mask layer and a material of the third interlayer dielectric layer may have a high selection ratio.

In an embodiment, the forming the resistive layer may include:
covering, by the resistive layer, the side wall and the bottom of the groove, the outer surface of the lower electrode, and a surface of the third interlayer dielectric layer.

In an embodiment, the forming the upper electrode may include:
forming an initial upper electrode covering all surfaces of the resistive layer and filling the groove; and
etching and removing part of the initial upper electrode between two adjacent lower electrodes, and stopping etching on the resistive layer to form the upper electrode.

According to the semiconductor structure and the preparation method thereof provided by the present disclosure, the lower electrode is formed into the concave structure, and the resistive layer covers the outer surface of the lower electrode and the side wall and bottom of the groove, so that the contact surface between the resistive layer and the lower electrode is increased, that is, the resistive area is increased, thereby reducing a forming voltage.

It should be understood that the content described in this section is not intended to identify critical or important features of the embodiments of the present disclosure, and is not used to limit the scope of the present disclosure either. Other features of the present disclosure will be easily understood through the following description.

### BRIEF DESCRIPTION OF THE DRAWINGS

By reading the following detailed description with reference to the accompanying drawings, the above and other objectives, features and advantages of the exemplary embodiments of the present disclosure will become easier to understand. In the drawings, several embodiments of the present disclosure are shown in an exemplary and non-limiting manner.

In the drawings, the same or corresponding reference numerals denote the same or corresponding parts.

FIG. 1 is a top view of a semiconductor structure according to an embodiment of the present disclosure.

FIG. 2 is a sectional view along an A-A′ direction in FIG. 1.

FIG. 3 is a sectional view along a B-B′ direction in FIG. 1.

FIG. 4 is a structural diagram of a resistive device according to an embodiment of the present disclosure.

FIG. 5 is a structural diagram of a semiconductor structure according to another embodiment of the present disclosure.

FIG. 6 is a flowchart of a preparation method for a semiconductor structure according to an embodiment of the present disclosure.

FIG. 7A to FIG. 7K are schematic diagrams of a semiconductor structure in the preparation process according to an embodiment of the present disclosure.

### DETAILED DESCRIPTION OF THE EMBODIMENTS

To make the objectives, features and advantages of the present disclosure apparent and easier to understand, the technical solutions in the embodiments of the present disclosure will be clearly and completely described below with reference to the accompanying drawings in the embodiments of the present disclosure. Apparently, the embodiments described are only some rather than all of the embodiments of the present disclosure. All other embodiments obtained by those skilled in the art based on the embodiments of the present disclosure without any creative efforts shall fall within the protection scope of the present disclosure.

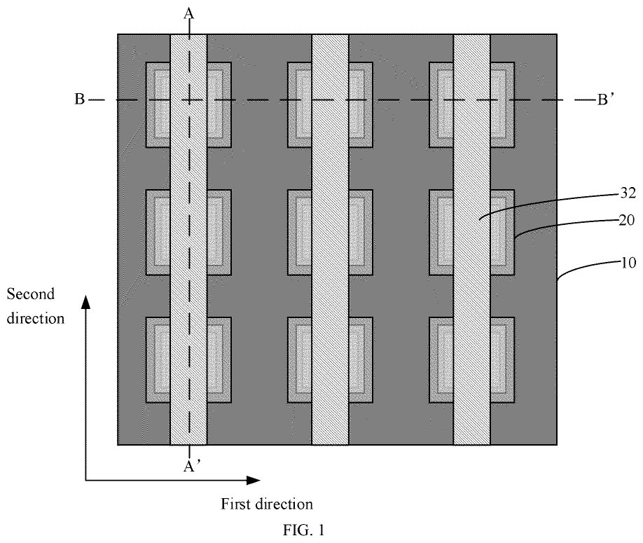

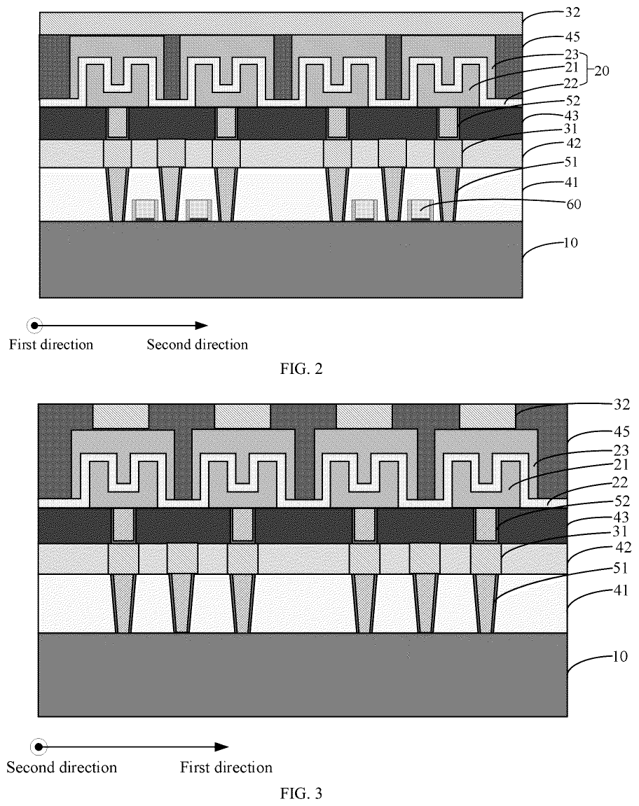

Embodiments of the present disclosure provide a semiconductor structure. FIG. 1 is a top view of a semiconductor structure according to an embodiment of the present disclosure; FIG. 2 is a sectional view along an A-A′ direction in FIG. 1; and FIG. 3 is a sectional view along a B-B′ direction in FIG. 1.

As shown in FIG. 2, the semiconductor structure includes:
a substrate 10;
a plurality of resistive devices 20, disposed on the substrate 10. Each of the resistive devices 20 includes a lower electrode 21, a resistive layer 22 and an upper electrode 23, a groove is formed in the lower electrode 21 to form a concave structure, the resistive layer 22 covers a side wall and a bottom of the groove and an outer surface of the lower electrode 21, and the upper electrode 23 covers a surface of the resistive layer 22 and fills the groove.

In some embodiments, the substrate 10 may be an elemental semiconductor material substrate (such as a silicon substrate, a germanium substrate and the like), a composite semiconductor material substrate (such as a germanium-silicon substrate and the like), a silicon on insulator (SOI) substrate, a germanium on insulator (GOI) substrate and the like.

Continuously referring to FIG. 2, the semiconductor structure further includes: a first interlayer dielectric layer 41, a second interlayer dielectric layer 42 and a third interlayer dielectric layer 43 which are sequentially stacked on the substrate 10.

A material of the first interlayer dielectric layer 41 includes, but is not limited to an insulating material such as silicon oxide, silicon nitride, silicon oxynitride and the like; a material of the second interlayer dielectric layer 42 and the material of the first interlayer dielectric layer 41 are identical, as long as there is a sufficient etching selection ratio; and a material of the third interlayer dielectric layer 43 includes, but is not limited to plasma enhanced oxide (PEOX).

The semiconductor structure further includes: a first contact via 51, disposed in the first interlayer dielectric layer 41 and penetrating through the first interlayer dielectric layer 41; a plurality of first metal layers 31, disposed in the second interlayer dielectric layer 42 and penetrating through the second interlayer dielectric layer 42, the first metal layers 31 being electrically connected to the lower electrode 21; and a second contact via 52, disposed in the third interlayer dielectric layer 43 and penetrating through the third interlayer dielectric layer 43.

Specifically, the first metal layer 31 is connected to the substrate 10 through the first contact via 51, and is electrically connected to the lower electrode 21 through the second contact via 52.

A material of the first metal layers 31 includes, but is not limited to copper. The first contact via 51 and the second contact via 52 may be of a double-layer structure, and materials of the first contact via 51 and the second contact via 52 may include titanium nitride disposed on an outer layer and tungsten disposed on an inner layer.

The semiconductor structure further includes: a grid electrode structure 60 disposed in the first interlayer dielectric layer 41, and the grid electrode structure 60 includes a grid dielectric layer and a grid electrode conductive layer disposed on the grid dielectric layer. A side wall of the grid electrode structure 60 is also covered with a side wall structure (not shown in figures).

As shown in FIG. 1, a plurality of resistive devices 20 are arranged in an array in a first direction and a second direction, the first direction and the second direction are parallel to a plane of the substrate 10, and the first direction intersects with the second direction.

As shown in FIG. 2, the resistive devices 20 are disposed on the third interlayer dielectric layer 43, and each of the resistive devices 20 includes the lower electrode 21, the resistive layer 22 and the upper electrode 23.

The groove is formed in the lower electrode 21 to form the concave structure.

The resistive layer 22 covers the side wall and the bottom of the groove and covers the outer surface of the lower electrode 21, and the resistive layer 22 also covers a surface of the third interlayer dielectric layer 43, so that the resistive layers 22 of the adjacent resistive devices 20 are connected together, and the upper electrode 23 and the lower electrode 21 can be isolated better, thereby avoiding short circuit.

The upper electrode 23 covers the surface of the resistive layer 22 and fills the groove. In an embodiment, the adjacent upper electrodes 23 are disconnected to prevent short circuit.

A material of the lower electrode 21 includes, but is not limited to titanium nitride. A material of resistive layer 22 includes transition metal oxide, specifically, for example, hafnium oxide, aluminum oxide and the like. A material of the upper electrode 23 includes, but is not limited to titanium nitride.

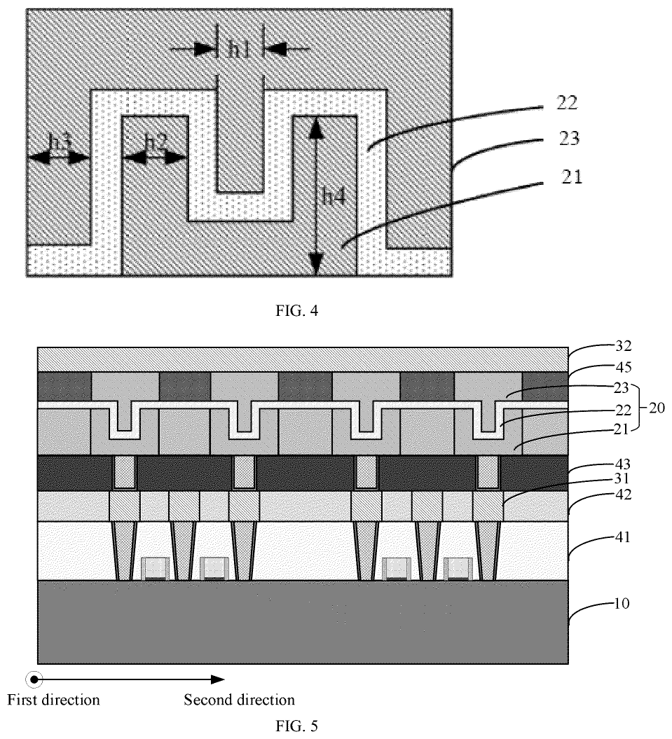

FIG. 4 is a structural diagram of a resistive device according to an embodiment of the present disclosure. As shown in FIG. 4, the width of the upper electrode 23 in the groove is h1, and in an embodiment, h1 may be 30 nm; the width of the lower electrode 21 disposed between the resistive layer 22 disposed on the inner side wall in the groove and the resistive layer 22 disposed on the outer side wall of the lower electrode 21 is h2, and in an embodiment, h2 is 30 nm; the width of the upper electrode 23 covering the outer side wall of the resistive layer 22 is h3, and in an embodiment, h3 is 30 nm; and the overall height of the lower electrode 21 is h4, and in an embodiment, h4 is 130 nm. In the present disclosure, the number of contact surfaces between the lower electrode 21 and the resistive layer 22 is as many as 13, such that a resistive area is increased.

In the embodiments of the present disclosure, the resistive area is determined by the contact area of the lower electrode 21 and the resistive layer 22, so the resistive area can be adjusted by controlling the overall height of the lower electrode 21 and the height of the groove, thereby achieving a three-dimensional structure and increasing the integration level.

FIG. 5 is a structural diagram of a semiconductor structure according to another embodiment of the present disclosure. As shown in FIG. 5, the resistive layer covers the side wall and the bottom of the groove and an upper surface of the lower electrode 21, and does not cover the side wall of the lower electrode 21. In this embodiment, the resistive area can be adjusted by controlling the transverse width of the lower electrode 21 and the height of the groove.

Continuously referring to FIG. 2, the semiconductor structure further includes: a first dielectric layer 45, disposed between two adjacent upper electrodes 23 to isolate the two adjacent upper electrodes 23, and the first dielectric layer 45 is an ultralow K material.

The first dielectric layer 45 adopts the ultralow K material, which can reduce parasitic capacitance, because there will be the parasitic capacitance between the resistive devices. If a high K material is used, the parasitic capacitance will be directly formed.

Continuously referring to FIG. 2, the semiconductor structure further includes: a plurality of second metal layers 32, disposed on the resistive devices 20 and electrically connected to the upper electrode 23.

As shown in FIG. 1, the second metal layers 32 are arranged in a first direction and extend in a second direction.

As shown in FIG. 3, the second metal layers 32 are disposed in the first dielectric layer 45.

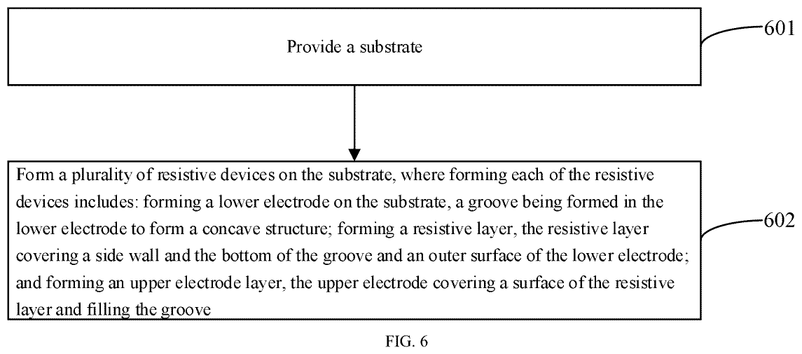

The embodiments of the present disclosure further provide a preparation method for a semiconductor structure. FIG. 6 is a flowchart of a preparation method for a semiconductor structure according to an embodiment of the present disclosure. Referring to FIG. 6, the method includes the following steps:
Step 601: a substrate is provided; and
Step 602: a plurality of resistive devices are formed on the substrate, where forming each of the resistive devices includes:
a lower electrode is formed on the substrate, and a groove is formed in the lower electrode to form a concave structure;
a resistive layer is formed, the resistive layer covers a side wall and a bottom of the groove and an outer surface of the lower electrode; and
an upper electrode is formed, and the upper electrode covers a surface of the resistive layer and fills the groove.

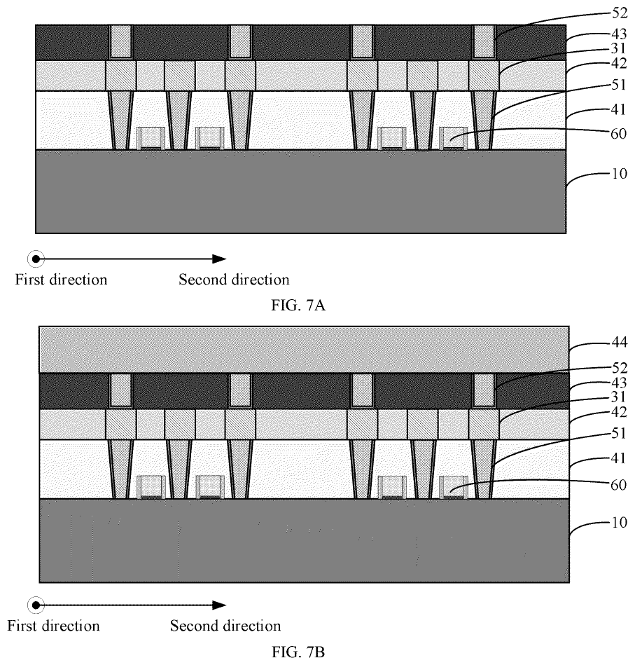

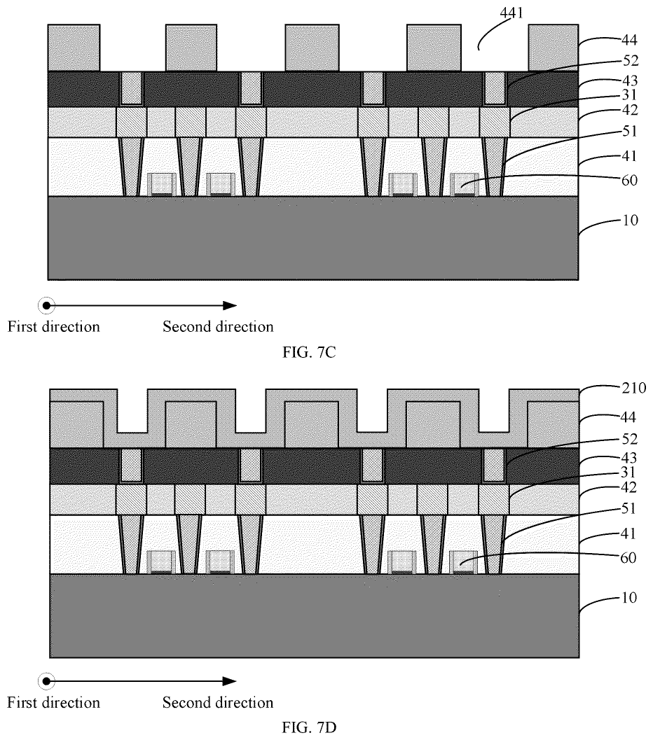

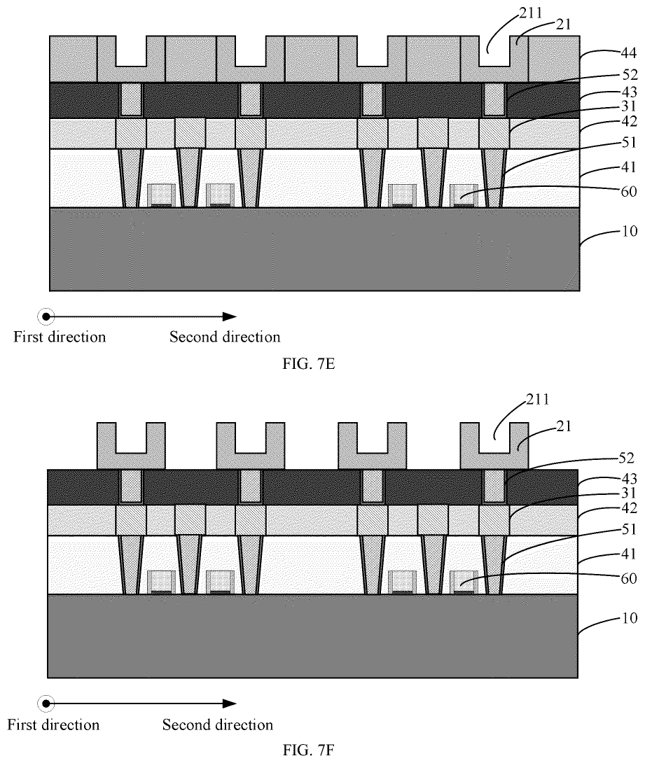

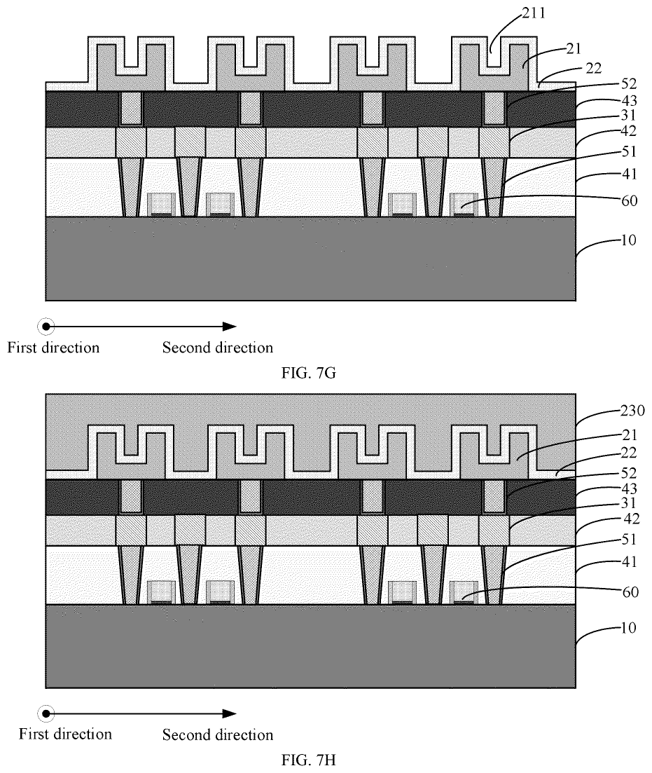

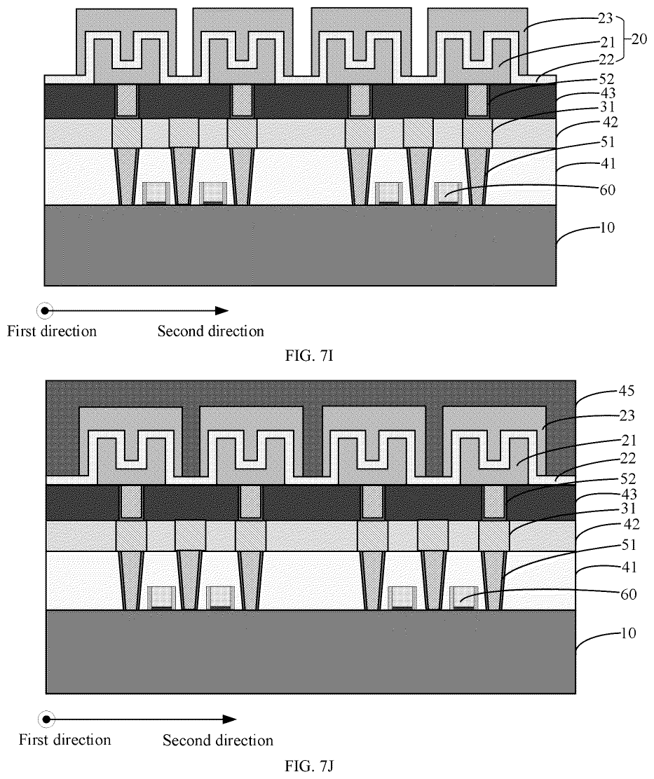

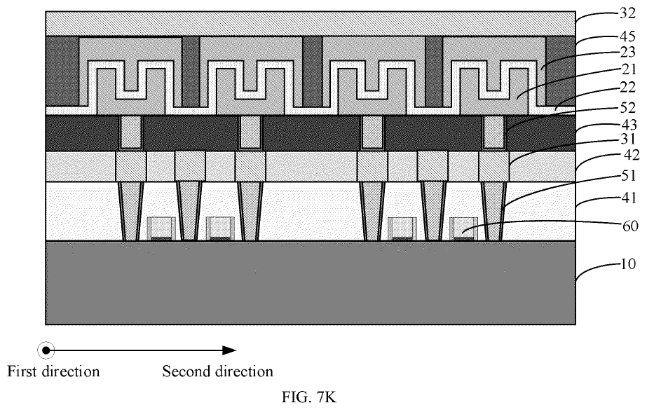

The preparation method for the semiconductor structure provided by the embodiments of the present disclosure is further described below in detail in combination with specific embodiments. FIG. 7A to FIG. 7K are schematic diagrams of a semiconductor structure in the preparation process according to an embodiment of the present disclosure.

First, referring to FIG. 7A, the step 601 is performed. A substrate 10 is provided.

In an embodiment, the substrate 10 may be an elemental semiconductor material substrate (such as a silicon substrate, a germanium substrate and the like), a composite semiconductor material substrate (such as a germanium-silicon substrate and the like), a silicon on insulator (SOI) substrate, a germanium on insulator (GOI) substrate and the like.

A first interlayer dielectric layer 41, a second interlayer dielectric layer 42 and a third interlayer dielectric layer 43 are sequentially formed on the substrate 10.

In actual operation, the first interlayer dielectric layer 41, the second interlayer dielectric layer 42 and the third interlayer dielectric layer 43 may be formed through chemical vapor deposition (CVD), physical vapor deposition (PVD), atomic layer deposition (ALD) or other deposition methods.

A material of the first interlayer dielectric layer 41 includes, but is not limited to an insulating material such as silicon oxide, silicon nitride, silicon oxynitride and the like; a material of the second interlayer dielectric layer 42 and the material of the first interlayer dielectric layer 41 are identical, as long as there is a sufficient etching selection ratio; and a material of the third interlayer dielectric layer 43 includes, but is not limited to plasma enhanced oxide (PEOX).

A first contact via 51 is formed in the first interlayer dielectric layer 41; a first metal layer 31 is formed in the second interlayer dielectric layer 42, and the first metal layer 31 is disposed on the first contact via 51 and connected to the substrate 10 through the first contact via 51; and a second contact via 52 is formed on the third interlayer dielectric layer 43, the second contact via 52 is disposed on the first metal layer 31, and the first metal layer 31 is electrically connected to the subsequently formed lower electrode 21 through the second contact via 52.

A material of the first metal layer 31 includes, but is not limited to copper. The first contact via 51 and the second contact via 52 may be of a double-layer structure, and materials of the first contact via 51 and the second contact via 52 may include titanium nitride disposed on an outer layer and tungsten disposed on an inner layer.

A grid electrode structure 60 is formed in the first interlayer dielectric layer 41, and the grid electrode structure 60 includes a grid dielectric layer and a grid electrode conductive layer disposed on the grid dielectric layer. A side wall of the grid electrode structure 60 is also covered with a side wall structure (not shown in figures).

Then, referring to FIG. 7B to FIG. 7I, the step S602 is performed, and a plurality of resistive devices 20 are formed on the substrate 10. Forming each of the resistive devices 20 includes: the lower electrode 21 is formed on the substrate 10, and the groove 211 is formed in the lower electrode 21 to form the concave structure; the resistive layer 22 is formed, and the resistive layer 22 covers the side wall and the bottom of the groove 211 and the outer surface of the lower electrode 21; and the upper electrode 23 is formed, and the upper electrode 23 covers the surface of the resistive layer 22 and fills the groove 211.

Referring to FIG. 7B, a first mask layer 44 is formed on the third interlayer dielectric layer 43.

In actual operation, the first mask layer 44 may be formed through chemical vapor deposition (CVD), physical vapor deposition (PVD), atomic layer deposition (ALD) or other deposition methods.

The first mask layer 44 may be an oxide layer.

Then, referring to FIG. 7C, the first mask layer 44 is etched to form a plurality of first grooves 441 penetrating through the first mask layer 44.

In actual operation, a photoresist layer (not shown in figures) may be formed on the first mask layer 44, the photoresist layer is patterned through photoetching to form a first groove pattern on the photoresist layer, and then the first mask layer 44 is etched by using the first groove pattern to form the first grooves 441 penetrating through the first mask layer 44.

An etching process may be wet etching process, or may be a dry etching process, preferably, the dry etching process. The dry etching process includes, but is not limited to at least one of ion milling etching, plasma etching, reactive ion etching or laser ablation.

Then, referring to FIG. 7D, an initial lower electrode 210 covering side walls and bottoms of the first grooves 441 and a surface of the first mask layer 44 is formed.

In actual operation, the initial lower electrode 210 may be formed through chemical vapor deposition (CVD), physical vapor deposition (PVD), atomic layer deposition (ALD) or other deposition methods.

Then, referring to FIG. 7E, the initial lower electrode 210 disposed on the surface of the first mask layer 44 is etched and removed, and the initial lower electrode 210 covering the side walls and the bottoms of the first grooves 441 are retained to form the lower electrode 21, where the groove 211 is formed in the lower electrode 21 to form the concave structure.

A material of the lower electrode 21 includes, but is not limited to titanium nitride.

Then, referring to FIG. 7F, the first mask layer 44 is removed.

In an embodiment, a material of the first mask layer 44 and a material of the third interlayer dielectric layer 43 have a high selection ratio. In this way, when the first mask layer 44 is removed by a buffered oxide etch (BOE) solution, the removal of the third interlayer dielectric layer 43 can be avoided. In an embodiment, a silicon nitride layer may also be formed between the third interlayer dielectric layer 43 and the first mask layer 44, thereby further protecting the third interlayer dielectric layer 43.

Then, referring to FIG. 7G, the resistive layer 22 is formed, and the resistive layer 22 covers the side wall and the bottom of the groove 211, the outer surface of the lower electrode 21, and a surface of the third interlayer dielectric layer 43, so that the resistive layers 22 of the adjacent resistive devices 20 can be connected together, and the upper electrode 23 and the lower electrode 21 can be isolated better, thereby avoiding short circuit.

In actual operation, the resistive layer 22 may be formed through chemical vapor deposition (CVD), physical vapor deposition (PVD), atomic layer deposition (ALD) or other deposition methods. In a preferred embodiment, the corner thinning problem can be avoided by the atomic layer deposition method.

A material of resistive layer 22 includes transition metal oxide, specifically, for example, hafnium oxide, aluminum oxide and the like.

Then, referring to FIG. 7H, an initial upper electrode 230 covering all surfaces of the resistive layer 22 and filling the groove 211 is formed.

In actual operation, the initial upper electrode 230 may be formed through chemical vapor deposition (CVD), physical vapor deposition (PVD), atomic layer deposition (ALD) or other deposition methods. In a preferred embodiment, the atomic layer deposition method may be adopted.

After the initial upper electrode 230 is formed, the initial upper electrode 230 may also be subjected to chemical mechanical polishing (CMP).

Then, referring to FIG. 7I, part of the initial upper electrode 230 between two adjacent lower electrodes 21 is etched and removed, and etching is stopped on the resistive layer 22 to form the upper electrode 23.

Part of the initial upper electrode 230 between the two adjacent lower electrodes 21 is etched and removed, so that the adjacent upper electrodes 23 can be disconnected, thereby preventing short circuit.

In an embodiment, the etching process may be a reactive sputter etching (RSE) process, and side wall damage can be reduced by using the RSE.

A material of the upper electrode 23 includes, but is not limited to titanium nitride.

In an embodiment, as shown in FIG. 1, a plurality of resistive devices 20 are arranged in an array in a first direction and a second direction, the first direction and the second direction are parallel to a plane of the substrate 10, and the first direction intersects with the second direction.

As shown in FIG. 4, the width of the upper electrode 23 in the groove is h1, and in an embodiment, h1 may be 30 nm; the width of the lower electrode 21 disposed between the resistive layer 22 disposed on the inner side wall in the groove and the resistive layer 22 disposed on the outer side wall of the lower electrode 21 is h2, and in an embodiment, h2 is 30 nm; the width of the upper electrode 23 covering the outer side wall of the resistive layer 22 is h3, and in an embodiment, h3 is 30 nm; and the overall height of the lower electrode 21 is h4, and in an embodiment, h4 is 130 nm. In the present disclosure, the number of contact surfaces between the lower electrode 21 and the resistive layer 22 is as many as 13, such that a resistive area is increased.

In the embodiments of the present disclosure, the resistive area is determined by the contact area of the lower electrode 21 and the resistive layer 22, so the resistive area can be adjusted by controlling the overall height of the lower electrode 21 and the height of the groove, thereby achieving a three-dimensional structure and increasing the integration level.

Then, referring to FIG. 7J, a first dielectric layer 45 disposed between two adjacent upper electrodes 23 is formed to isolate the two adjacent upper electrodes 23, and the first dielectric layer 45 is an ultralow K material.

The first dielectric layer 45 adopts the ultralow K material, which can reduce parasitic capacitance, because there will be the parasitic capacitance between the resistive devices. If a high K material is used, the parasitic capacitance will be directly formed.

Then, referring to FIG. 7K, a plurality of second metal layers 32 are formed, which are disposed on the resistive device 20 and electrically connected to the upper electrode 23.

Specifically, a photoresist layer (not shown in figures) may be formed on the first dielectric layer 45, the photoresist layer is patterned through photoetching to form a groove pattern disposed on the photoresist layer, then the first dielectric layer 45 is etched by using the groove pattern to form a groove extending into the first dielectric layer 45, the groove is exposed on the surface of the upper electrode 23, and a metal material is deposited in the groove to form the second metal layer 32.

As shown in FIG. 1, the second metal layers 32 are arranged in a first direction and extend in a second direction.

It should be understood that the steps may be reordered, added or deleted by using the flows in various forms, which are shown above. For example, the steps recorded in the present disclosure may be performed concurrently in order, or in a different order, provided that the desired result of the technical solutions disclosed in the present disclosure can be achieved, which is not limited herein.

In addition, the terms “first” and “second” are merely used for description purposes and cannot be interpreted as indicating or implying relative importance or implicitly indicating the number of technical features indicated. Therefore, the features defined with “first” and “second” can explicitly or implicitly include one or more features. In the description of the present disclosure, “a plurality of” means two or more than two, unless otherwise specified.

The above are only specific embodiments of the present disclosure, and are not intended to limit the scope of protection of the present disclosure, and any changes or substitutions that can readily occur to those skilled in the art within the scope of technology disclosed in the present disclosure should fall within the scope of protection of the present disclosure. Therefore, the scope of protection of the present disclosure shall be subject to the scope of protection of the claims.

What is claimed is:

1. A semiconductor structure, comprising:
a substrate;
a plurality of resistive devices, disposed on the substrate; wherein each of the plurality of resistive devices comprises a lower electrode, a resistive layer and an upper electrode; a groove is formed in the lower electrode to form a concave structure, the resistive layer covers a side wall and a bottom of the groove and an outer surface of the lower electrode, and the upper electrode covers a surface of the resistive layer and fills the groove.

2. The semiconductor structure according to claim 1, further comprising:
a first dielectric layer, disposed between two adjacent upper electrodes to isolate the two adjacent upper electrodes; wherein the first dielectric layer is an ultralow K material.

3. The semiconductor structure according to claim 1, further comprising:
a first interlayer dielectric layer, a second interlayer dielectric layer and a third interlayer dielectric layer, wherein the first interlayer dielectric layer, the second interlayer dielectric layer and the third interlayer dielectric layer are sequentially stacked on the substrate; wherein the plurality of resistive devices are disposed on the third interlayer dielectric layer; and
a plurality of first metal layers, disposed in the second interlayer dielectric layer and penetrating through the second interlayer dielectric layer; wherein the plurality of first metal layers are electrically connected to the lower electrode.

4. The semiconductor structure according to claim 1, further comprising:
a plurality of second metal layers, disposed on the plurality of resistive devices and electrically connected to the upper electrode.

5. A preparation method for a semiconductor structure, comprising:
providing a substrate;
forming a plurality of resistive devices on the substrate; wherein a step of forming each of the plurality of resistive devices comprises:
forming a lower electrode on the substrate, forming a groove in the lower electrode to form a concave structure;
forming a resistive layer, the resistive layer covering a side wall and a bottom of the groove and an outer surface of the lower electrode; and
forming an upper electrode, the upper electrode covering a surface of the resistive layer and filling the groove.

6. The preparation method for the semiconductor structure according to claim 5, further comprising:
forming a first dielectric layer disposed between two adjacent upper electrodes to isolate the two adjacent upper electrodes; wherein the first dielectric layer is an ultralow K material.

7. The preparation method for the semiconductor structure according to claim 5, wherein a step of forming the lower electrode comprises:
forming a first mask layer on the substrate;
etching the first mask layer to form a plurality of first grooves penetrating through the first mask layer;
forming an initial lower electrode covering side walls and bottoms of the plurality of first grooves and a surface of the first mask layer; and
etching and removing the initial lower electrode disposed on the surface of the first mask layer, and retaining the initial lower electrode covering the side walls and the bottoms of the plurality of first grooves to form the lower electrode; wherein the groove is formed in the lower electrode to form the concave structure.

8. The preparation method for the semiconductor structure according to claim 7, further comprising: before a step of forming the plurality of resistive devices,
forming a first interlayer dielectric layer, a second interlayer dielectric layer and a third interlayer dielectric layer, wherein the first interlayer dielectric layer, the second interlayer dielectric layer and the third interlayer dielectric layer are sequentially stacked on the substrate;
wherein the first mask layer is disposed on the third interlayer dielectric layer, and a material of the first mask layer and a material of the third interlayer dielectric layer have a high selection ratio.

9. The preparation method for the semiconductor structure according to claim 8, wherein a step of forming the resistive layer comprises:
covering, by the resistive layer, the side wall and the bottom of the groove, the outer surface of the lower electrode, and a surface of the third interlayer dielectric layer.

10. The preparation method for the semiconductor structure according to claim 9, wherein a step of forming the upper electrode comprises:
forming an initial upper electrode covering all surfaces of the resistive layer and filling the groove; and
etching and removing part of the initial upper electrode between two adjacent lower electrodes, and stopping etching on the resistive layer to form the upper electrode.
